(19) United States
(12) Patent Application Publication
(10) Pub. No.: US 2026/0008142 A1
(43) Pub. Date: Jan. 8, 2026

(54) WORKPIECE TRANSPORT WITH REDUCED PARTICLE GENERATION

(71) Applicant: TEXAS INSTRUMENTS INCORPORATED, Dallas, TX (US)

(72) Inventors: Rodolfo Medina, Wylie, TX (US); Jeremy Stufflebeem, Plano, TX (US); Melissa DeAlmeida, Garland, TX (US); Sunghak Kim, Allen, TX (US)

(21) Appl. No.: 19/096,694

(22) Filed: Mar. 31, 2025

Related U.S. Application Data
(60) Provisional application No. 63/666,931, filed on Jul. 2, 2024.

(51) Int. Cl. B23Q 1/25; H01L 21/677

(52) U.S. Cl. CPC B23Q 1/25; H01L 21/67727; H01L 21/6773

(57) ABSTRACT

Described examples include a material movement track having a base having a top surface, a first rail connected to the base and having a first major surface extending over the top surface, and a second rail connected to the base and having a second major surface extending over the top surface. The material movement track also has a first cover member extending from a first side of the base over the first rail and a second cover member extending from a second side of the base over the second rail and forming a gap between the first and second cover members.

### CROSS REFERENCE TO RELATED APPLICATIONS

This application claims the benefit under 35 U.S.C. § 119(e) to co-owned U.S. Provisional Patent Application Ser. No. 63/666,931, filed Jul. 2, 2024, which is hereby incorporated by reference in its entirety herein.

### TECHNICAL FIELD

Disclosed implementations relate generally to particle control in a low-particle (“cleanroom”) manufacturing facility. More particularly, but not exclusively, the disclosed implementations relate particle control related to material movement in a semiconductor manufacturing facility.

### BACKGROUND

Controlling airborne particles in a semiconductor manufacturing environment is critical to attaining high device yield. As feature sizes of semiconductors approach a few nanometers or less, the damage that particles can cause grows exponentially. Workers are a significant source of particulate contamination, which motivates minimizing the number of workers in low-particle areas. To reduce or minimize the need for human interaction in the semiconductor manufacturing process, material movement systems have been developed that shuttle containers for in-process semiconductor wafers between various tools that process the wafers. Such automated material movement may result in a significant reduction of particle generation, but further work is needed to meet increasingly stringent particle requirements.

### SUMMARY

In accordance with an example, a material movement track includes a base having a top surface, a first rail connected to the base and having a first major surface extending over the top surface, and a second rail connected to the base and having a second major surface extending over the top surface. The material movement track also includes a first cover member extending from a first side of the base over the first rail and a second cover member extending from a second side of the base over the second rail and forming a gap between the first and second cover members.

### BRIEF DESCRIPTION OF THE DRAWINGS

FIG. 1 is a schematic diagram of a manufacturing system, e.g. a semiconductor fabrication facility (or “fab”).

FIG. 2 is a diagram of an example workpiece carrier on a portion of a material movement track.

FIG. 3 is a cut-away view of an example workpiece carrier, such as the workpiece carrier of FIG. 2, on a portion of a material movement track that includes example cover members.

FIG. 4 is a cut-away view of an example workpiece carrier, such as the workpiece carrier of FIG. 2, on a portion of a material movement track that includes example cover members.

FIG. 5 is a cut-away view of another example of a workpiece carrier, such as the workpiece carrier of FIG. 2, on a portion of a material movement track that includes example cover members.

FIG. 6 is an exploded view of a portion of a material movement track and associated cover members.

FIG. 7 is an assembled view of a portion of a material movement track and cover members.

FIGS. 8A-C (collectively “FIG. 8”) are cut-away views of a material track and cover members.

FIGS. 9A-C (collectively “FIG. 9”) are cut-away views of a switch portion of a material movement track, and associated cover members.

FIG. 10 is a view of a section of track including mounting jigs that may be used to position cover members during attachment to a material movement track.

FIG. 11 is a view of an example material movement track portion, illustrating air flow around the track and a workpiece carrier in a background laminar airflow.

### DETAILED DESCRIPTION

In the drawings, corresponding numerals and symbols generally refer to corresponding parts unless otherwise indicated. The drawings are not necessarily drawn to scale.

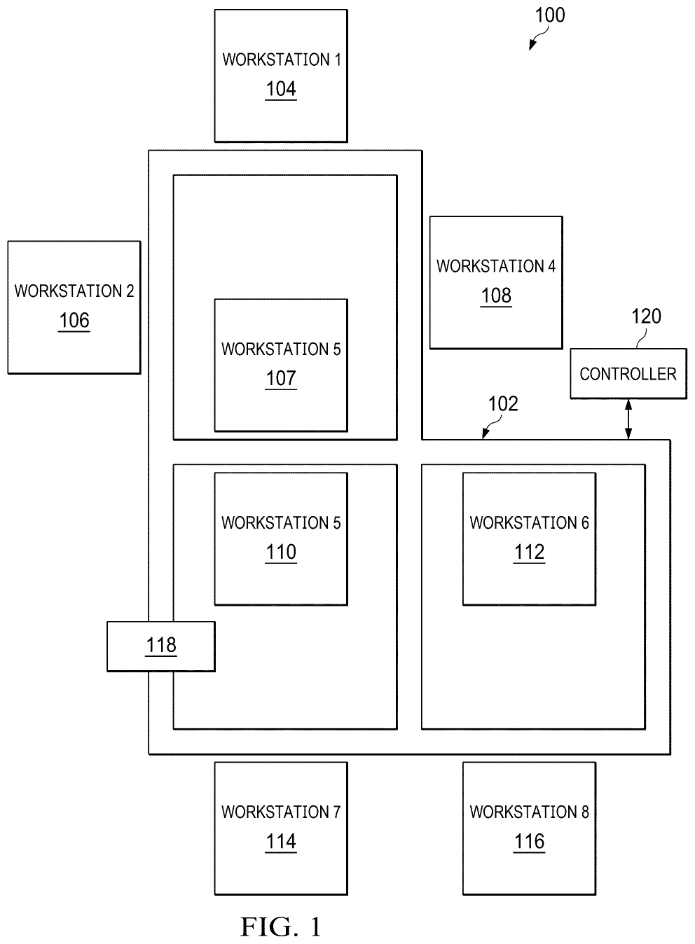

FIG. 1 is a schematic diagram of a manufacturing system 100, e.g. a semiconductor manufacturing facility (sometimes referred to as a “fab” or “cleanroom”). Track 102 is a material movement track that allows for transport of workpiece carrier (sometimes referred to as a “car”) 118 between workstations 104, 106, 107, 108, 110, 112, 114, and 116. In an example, a workpiece is a semiconductor wafer or several semiconductor wafers traveling in a suitable carrier. As explained further below, track 102 includes mechanisms for moving and directing workpiece carrier 118 under the control of controller 120 to the workstations in a planned order of operations. When workpiece carrier 118 is at an appropriate workstation, a loading mechanism at the workstation loads the workpiece into the workstation so that the workstation can perform the appropriate manufacturing step. Manufacturing system 100 is greatly simplified in the example of a semiconductor manufacturing systems. A typical manufacturing process may include hundreds of steps performed by dozens of types of workstations, such as a furnace, an ion implanter, a chemical vapor depositor, and a chemical/mechanical polisher. In addition, some process steps with greater latency may be duplicated to avoid processing bottlenecks. Additional tool redundancy may be provided to allow for maintenance and repairs while avoiding interruptions in the production line. Thus, to accommodate transport to all of these workstations, a large amount of track is typically necessary in a production facility.

In an example, track 102 is suspended from the ceiling of the cleanroom. The movement of the workpiece carrier 118 may create particles, e.g. by abrasion of wheels or bearings, or inadvertent contact between portions of the workpiece carrier 118 and the track 102. Most current semiconductor cleanrooms strive to achieve Class 1 or ISO 3 standards. In an example, the ISO 3 standard requires that airborne particles include no more than 35 particles per cubic meter (m⁻³) greater than 0.1 μm, ≤7/m⁻³ larger than 0.2 μm, ≤3/m⁻³ larger than 0.3 μm, and ≤1 particle larger than 0.5 μm. Therefore, to the extent that the material movement track may be a source of airborne particles, it may be necessary to prevent such particle from becoming airborne to meet the stringent requirements of Class 1 and/or ISO 3 particle standards.

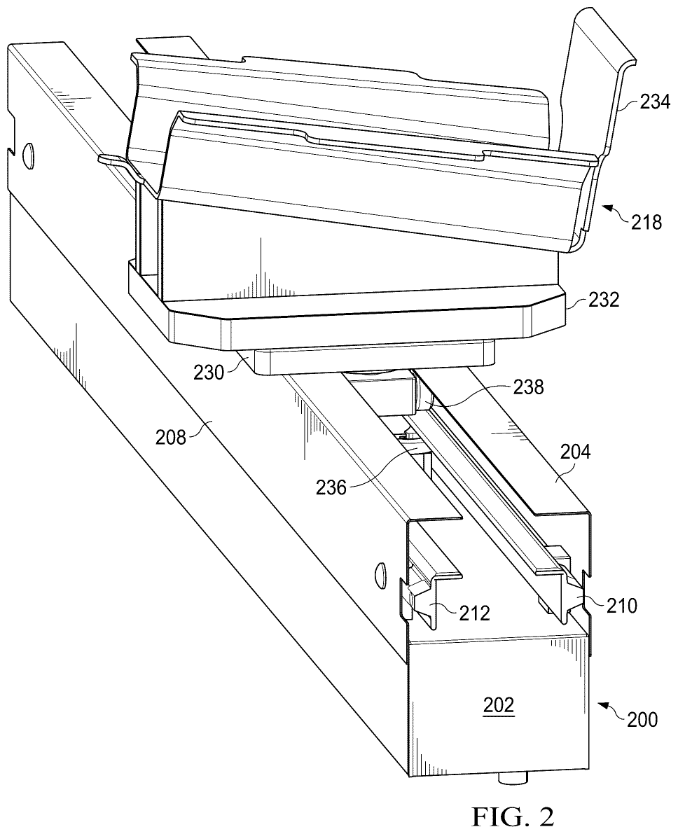

FIG. 2 is a diagram of an example car, or workpiece carrier, 218 on a portion of track 200 having a base 202. Track 200 is an example of track 102 (FIG. 1). Workpiece carrier 218 is an example of workpiece carrier 118 (FIG. 1). Rail 210 and rail 212 are mounted, e.g. to a top surface of the base 202. Bearings 236 engage rail 210 and rail 212 horizontally at a side portion of the rails such that horizontal movement is guided by the rails. The side, or vertical, portions of the rails 210/212 may be referred to as vertical major surfaces. Bearings 238 engage rail 210 and rail 212 vertically at a top portion of the rails such that the weight of puck 230 is supported. The top, or horizontal, portions of the rails 210/212 may be referred to as horizontal major surfaces. In this example, bearings 236 and bearings 238 are wheels implemented using a hard rubber or plastic. Puck 230 includes support for carrier base 232 and receiver 234. When workpiece carrier 218 is positioned by the appropriate workstation, the workstation will either remove the workpiece (not shown) from receiver 234 or place the workpiece onto receiver 234, as appropriate for the state of the workpiece. In an example, the workpiece may be a “boat” containing a dozen or more wafers or may be a vacuum sealed container such as a Front Opening Universal Pod (“FOUP”).

In this example, puck 230 includes permanent magnets (not shown). Coils (not shown) in base 202 are selectively energized under the control of controller 120 (FIG. 1) to create magnetic fields such that a motive force is created to push or pull workpiece carrier 218 along rail 210 and rail 212. This type of propulsion system avoids moving parts in the propulsion system to minimize generation of particles. In another example, puck 230 includes electric motors that are wirelessly controlled to provide propulsion. Such examples may produce more particles than examples relying on magnetic propulsion.

The example of FIG. 2 includes cover members 204, 208 each having a long axis parallel to a long axis of the base 202 and the direction of travel of the workpiece carrier 218. Each cover member 204, 208 has a first major surface that is about (within 5°) parallel to sides of the base 202, and a second major surface that is about (within 5°) perpendicular to the first major surface. The cover member 204 and cover member 208 extend over, and in some examples are mounted to, opposite sides of base 202. The first major surfaces of the cover members 204, 208 extend upward from the sides of the base 202 beyond rails 210, 212. The second major surface of the cover member 204 then extends horizontally toward the cover second major surface of the cover member 208, and the second major surface of cover member 208 extends horizontally toward the second major surface of the cover member 204. Cover member 204 and cover member 208 thus substantially enclose a space that includes the rails 210, 212 and the bearings 236, 238 while allowing freedom of movement for puck 230.

The cover members 204, 208 may be formed from any suitable material, e.g. metal, polymer or ceramic, and may optionally be coated or anodized in a manner that reduces particle generation. In a non-limiting example, cover member 204 and cover member 208 are formed from stainless steel, which among other properties is resistant to corrosion. In this and some other examples the cover members 204, 208 may be mechanically rigid and/or may have a low thermal expansion coefficient, thus resisting deformation due to temperature change and reducing risk of contact with the puck 230.

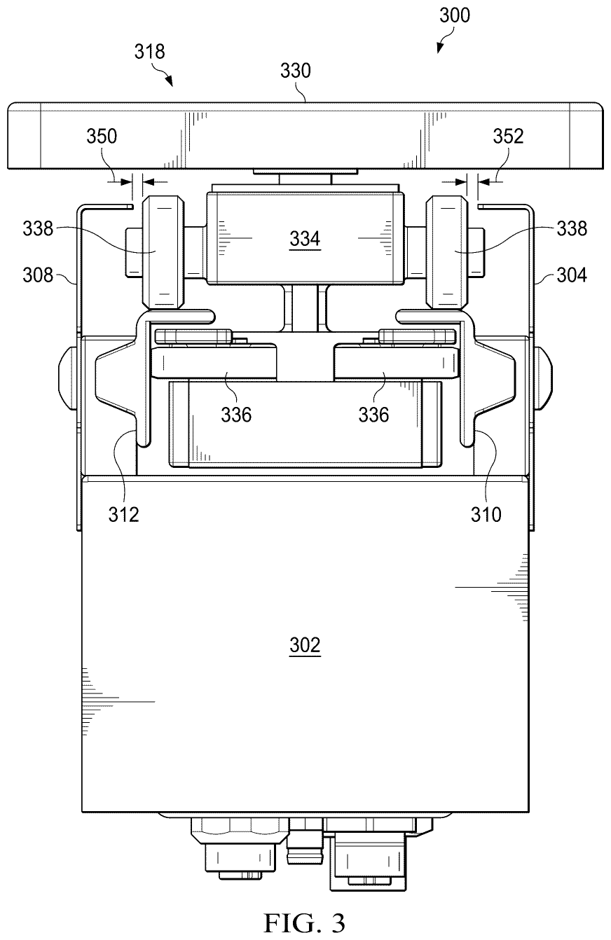

FIG. 3 is a cut-away view of an example of workpiece carrier 318 on a portion of track 300. Track 300 is an example of track 102 (FIG. 1). Workpiece carrier 318 is an example of workpiece carrier 118 (FIG. 1). Rail 310 and rail 312 are mounted to track base 302, e.g. by brackets (not shown). Bearings (or wheels) 336 position puck 330 horizontally between rail 310 and rail 312. Bearings 338 engage the horizontal portions of rail 310 and 312 to support the weight of puck 330. A lower portion 334 of puck 330 includes permanent magnets that are part of the propulsion system of puck 330 as explained hereinabove. Cover member 304 and cover member 308 are mounted to track base 302, directly or indirectly, and extend vertically as far as practicable given the wide upper portion of puck 330 portions having horizontal surfaces. The vertical surfaces of the cover members 304 and 308 may be regarded as vertical major surfaces. The horizontal surfaces of the cover members 304 and 308 may be regarded as horizontal major surfaces oriented normal (or orthogonal) to the horizontal surfaces. In some arrangements, as illustrated, horizontal surfaces of the cover members 304 and 308 extend at least to the rotational axes of the bearings 338, but do not extend to the tops of the bearings 338. Also in some arrangements, the horizontal surfaces of the cover members 304 and 308 do not extend directly over the horizontal surfaces of the rails 310, 312. The vertical surfaces extend to a height above the rails 310, 312. Cover member 304 extends horizontally to gap 350 between cover member 304 and one bearing 336, and cover member 308 extends to gap 352 between cover member 308 and the other bearing 338. The gaps 350, 352 may be determined to be as close as practicable to bearings 338 without contacting bearings 338 when puck 330 is moving, e.g. 3-10 mm. Thus the cover members 304 and 308 partially enclose an interior space or volume within which the bearings 336, 338 operate when the puck 330 is moving.

The cover members 304, 308 define sides of a substantially enclosed space within which is located the rails 310, 312 and the bearings 336, 338. During movement of the workpiece carrier 318, including the puck 330, contact between the bearings and the rails generally produce particles that may be metallic or nonmetallic depending on the materials of the various contacting components. In the absence of the cover members 304, 308, such particles may become airborne and float or fall onto production material, and may cause the manufacturing facility to exceed permissible particle limits of the applicable standard, such as ISO 3. But with the presence of the cover members 304, 308, particles generated within the substantially enclosed space are generally isolated from airflow outside the enclosed space, and may fall to the top surface of the track base 302. Thus, such particles are effectively isolated from the fab environment, and do not add to the detectable particle count and do not contact production material.

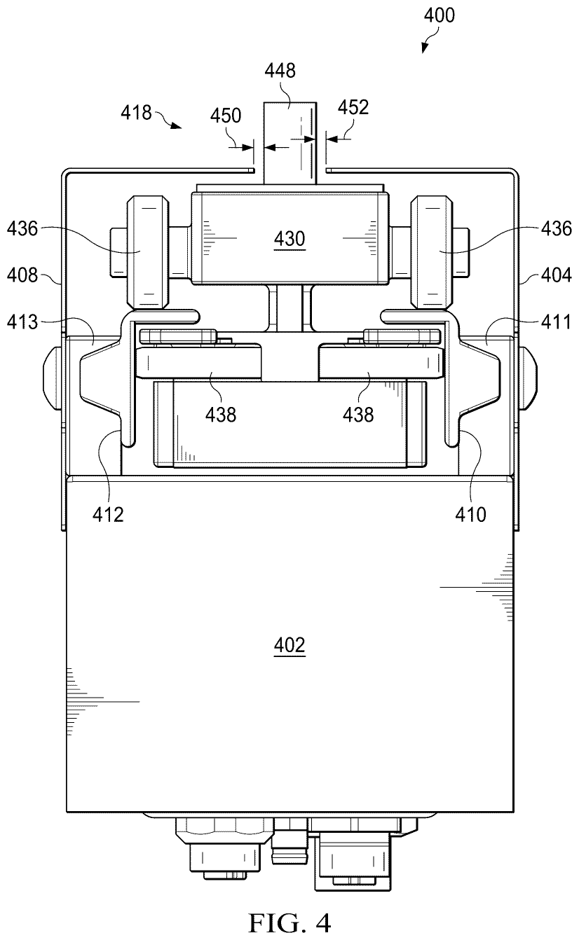

FIG. 4 is a cut-away view of another example of workpiece carrier 418 of FIG. 1. Track 400 is an example of track 102 (FIG. 1). Rail 410 and rail 412 are mounted to track base 402 using bracket 411 and bracket 413, respectively. Bearings 436 engage rail 410 and rail 412 vertically, and bearings 438 engage rail 410 and rail 412 horizontally. Cover member 404 is mounted to track base 402 using bracket 411, and cover member 408 is mounted to track base 402 using bracket 413. The vertical surfaces of the cover members 404 and 408 may be regarded as vertical major surfaces, and the horizontal surfaces of the cover members 404 and 408 may be regarded as horizontal major surfaces. In the illustrated arrangement the horizontal major surfaces of the cover members 404 and 408 extend past the rotational axes of the bearings 436 and directly over the horizontal surfaces of the rails 410, 412. In some examples, as illustrated, the cover members 404 and 408 extend past the rails 410, 412 toward a midpoint between the vertical major surfaces of the cover members 404 and 408. Extending vertically above puck 430 is extension 448. A receiver (not shown) may be mounted on the distal end of extension 448. An example receiver is receiver 234 (FIG. 2). An advantage of using extension 448 is that the horizontal extensions of cover members 404 and 408 can extend to gap 450 and gap 452, respectively. The gaps 450, 452 may be, e.g. 2-10 mm. Thus, cover member 404 and cover member 408 fully cover bearings 436 and substantially enclose an interior space or volume within which the bearings 436, 438 operate when the puck 430 is moving. The cover members 404 and 408 more completely enclose the interior space in which the rails 410, 412 and bearings 436, 438 are located than the example of FIG. 3. This configuration is expected to provide better protection from particles that may be formed by the motion of the puck 430 along the track 400.

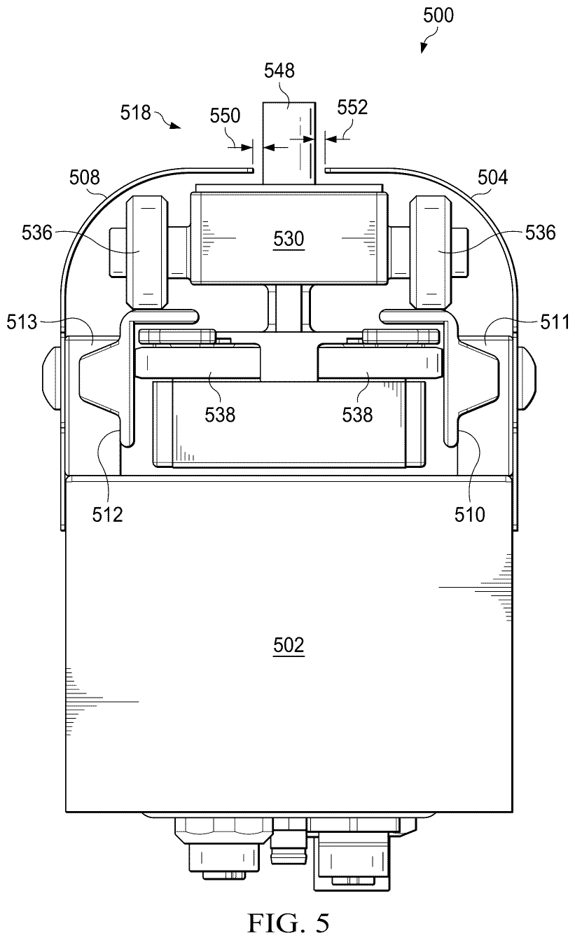

FIG. 5 is a cut-away view of another example of workpiece carrier 518 of FIG. 1. Track 500 is an example of track 102 (FIG. 1). Rail 510 and rail 512 are mounted to track base 502 using bracket 511 and bracket 513, respectively. Bearings 536 engage rail 510 and rail 512 vertically. Bearings 538 engage rail 510 and rail 512 horizontally. Cover member 504 is mounted to track base 502 using bracket 511. Cover member 508 is mounted to track base 502 using bracket 513. In contrast to cover member 404 and cover member 408 (FIG. 4), cover member 504 and cover member 508 are non-planar, e.g. have a smooth transition from a vertical surface to a horizontal surface to gaps 552, 552, respectively. The cover members 504, 508 may be regarded as having a single major surface with vertical and horizontal portions. This configuration of cover member 504 and cover member 508 may provide more rigidity at the expense of more complex fabrication. More generally, the cover members may have one of a multitude of cross-sectional profiles, including two or more planar portions and/or one or more curved portions. Thus, a wide variety of cover member configurations may be effectively employed. Cover member configurations are not limited to the configurations described in these example implementations.

Analogously to the example of the workpiece carrier 418, extension 548 projects vertically above puck 530. A receiver (not shown) may be mounted on the distal end of extension 548, where the receiver 234 (FIG. 2) is one example. Also analogous to the workpiece carrier 418 example, the cover member 504 and cover member 508 extend to gap 550 and gap 552, respectively, thereby substantially enclosing an interior space or volume within which the moving components are located. Thus, cover member 504 and cover member 508 fully cover bearings 536 and 538, and particles resulting from their movement are expected to be substantially confined to the interior space.

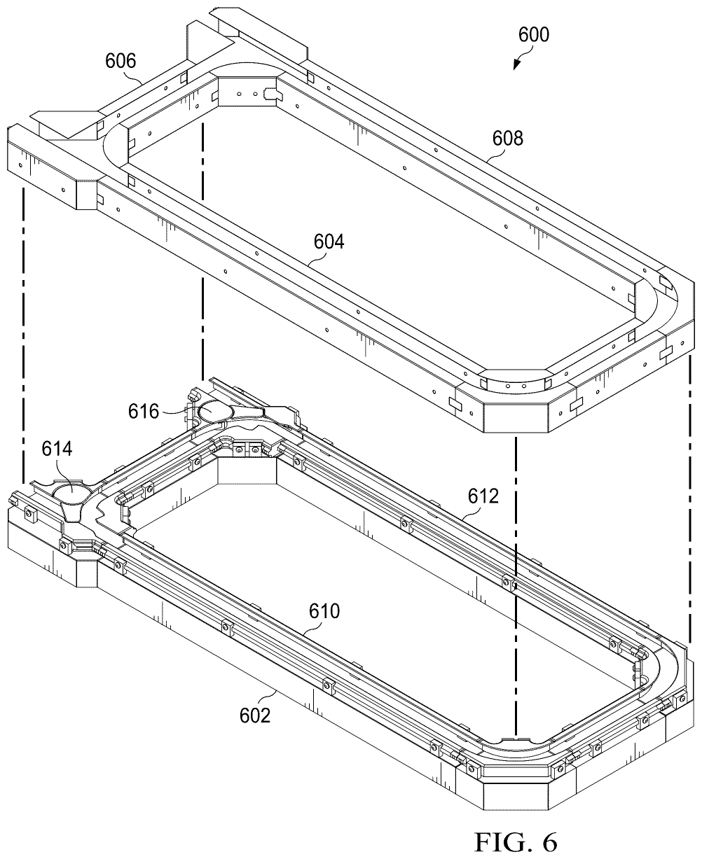

FIG. 6 is an exploded view of a portion of track 600. Track 600 is an example of track 102 (FIG. 1), and includes rail 610 and rail 612 mounted to base 602. The illustrated example may implement a parking loop for production material that, e.g., is waiting for availability of the workstation. Switch 614 and switch 616 may direct a car on rails 610 and 612 in one of multiple directions depending on input from a controller such as the controller 120, (FIG. 1) and the destination workstation. A cover assembly includes cover member 604, cover member 606, and cover member 608, which together generally follow the path provided by the rails 610, 612 and base 602 to which the rails are attached. In this example, the cover assembly includes expanded openings above switch 614 and switch 616 to accommodate the divergent paths the car may possibly take.

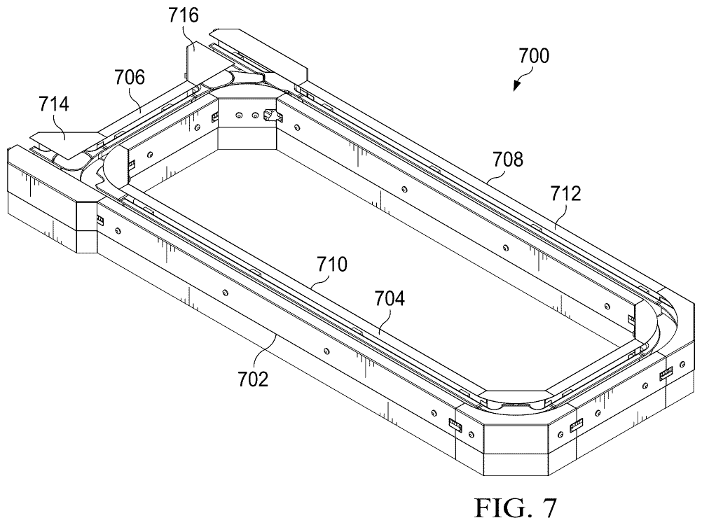

FIG. 7 is an assembled view of a portion of track 700. Track 700 is an example of track 600 (FIG. 6). Rail 710 and rail 712 are mounted to base 702. Switch 714 and switch 716 direct a car on rail 710 and rail 712 in one of two directions depending on input from a controller (not shown) and the destination workstation. Cover member 704, cover member 706, and cover member 708 mount onto base 702. In this example, the combined cover members include expanded openings above switch 714 and switch 716 to accommodate the divergent paths the car may possibly take.

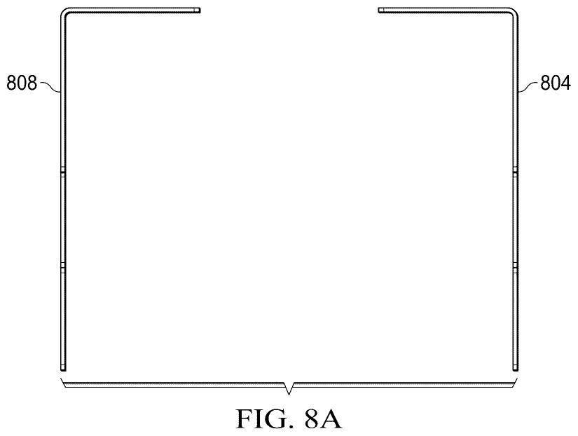

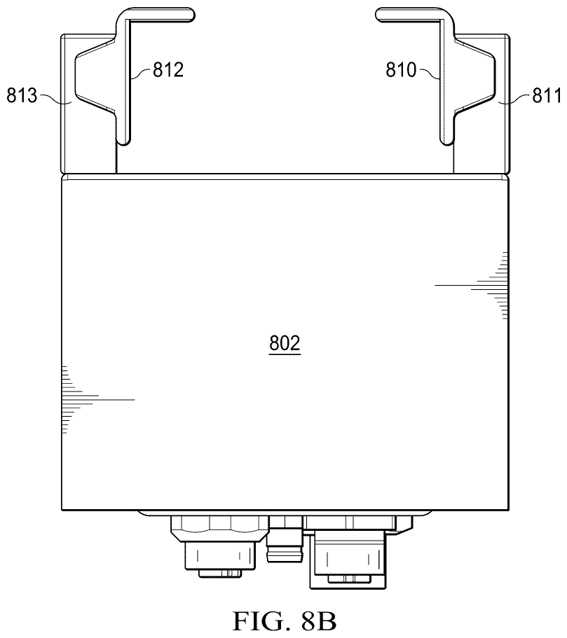

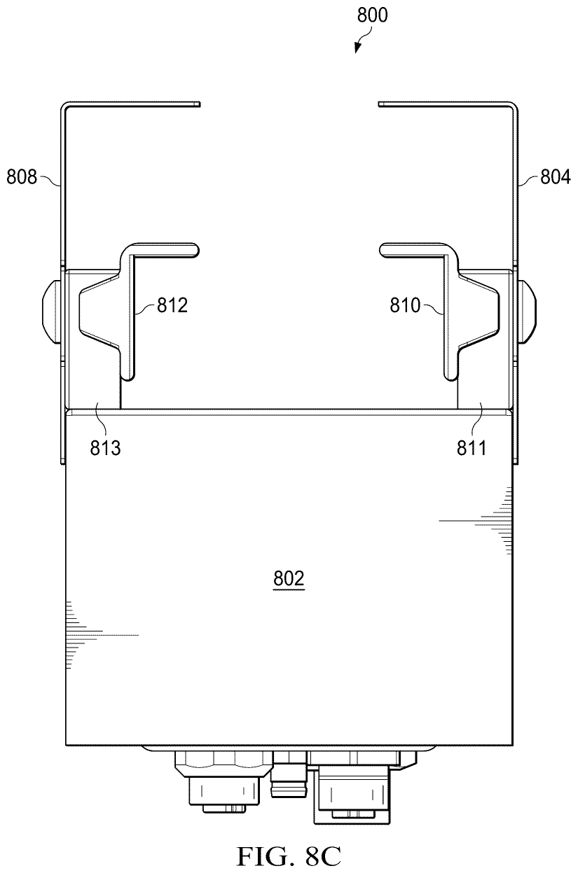

FIGS. 8A-C (collectively “FIG. 8”) are a cut-away view of track 800. Track 800 is an example of track 102 (FIG. 1). Cover member 804 and cover member 808 are shown in FIG. 8A. Rail 810 and rail 812 are mounted to base 802 using bracket 811 and bracket 813, respectively, as shown in FIG. 8B. FIG. 8C shows the components of FIGS. 8A and 8B assembled so that any particles formed by movement along rail 810 and rail 812 are contained (as much as possible) within the space defined by cover member 804 and cover member 808.

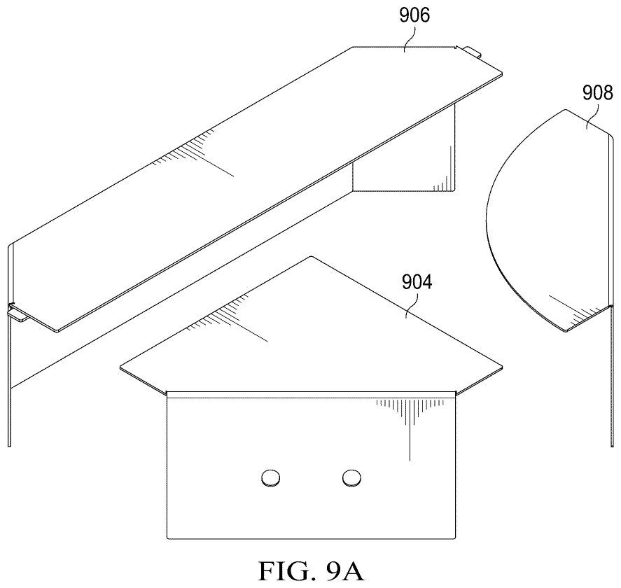

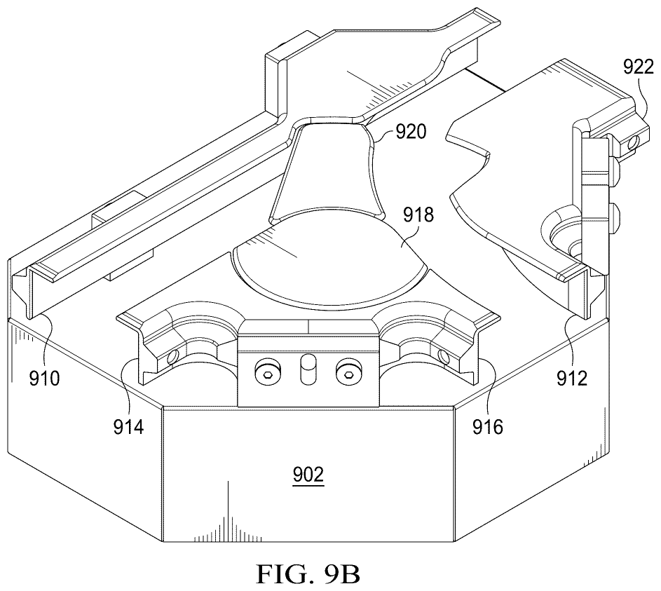

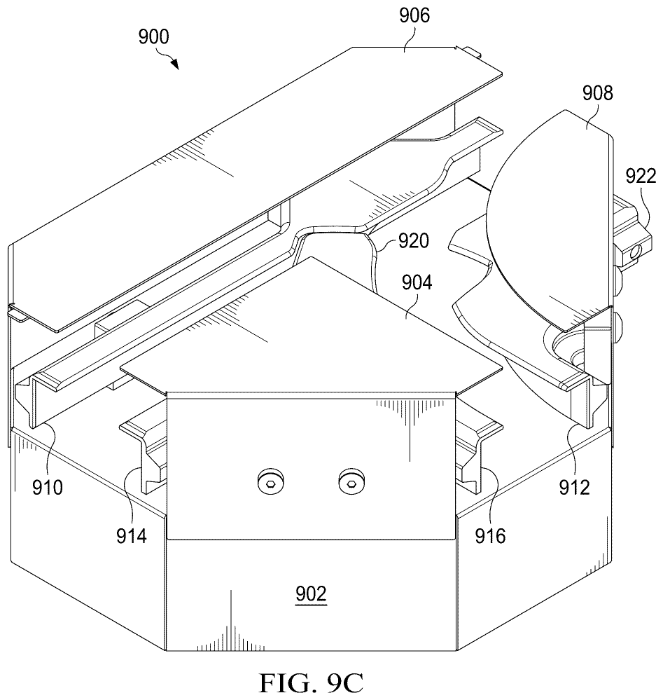

FIGS. 9A-C (collectively “FIG. 9”) are a cut-away view of switch assembly 900. Switch assembly 900 is an example of switch 614 or 616 (FIG. 6). Cover member 904, cover member 906, and cover member 908 are shown in FIG. 9A. Rail 910, rail 912, rail 914, and rail 916 are mounted to base 902, as shown in FIG. 9B. Switch actuator 918 is mounted to base 902 and is coupled to an actuator (not shown) in base 902. Arm 920 is mounted on switch actuator 918. In the position shown in FIG. 9B, a car entering from the top right of the figure is directed to the outlet formed by rail 912 and 916. If the arm is moved to the right into slot 922 in rail 912, a car entering from the top right of the figure is directed to the outlet formed by rail 910 and 914. A larger opening between the cover members may be necessary to accommodate the change of path direction of the car within the switch assembly 900. The illustrated example includes such a larger opening, e.g. between the rail 912 and the rail 916. Such occasional larger openings between adjacent rails is not expected to significantly adversely affect fab particle counts.

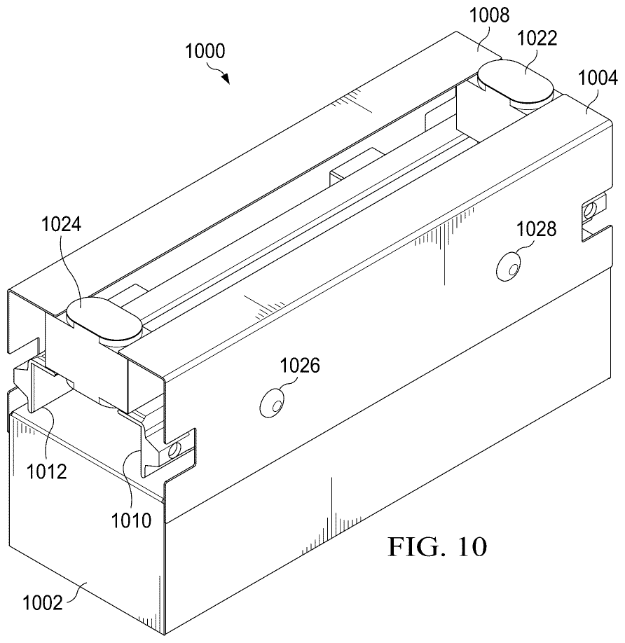

FIG. 10 is a view of a section of track 1000. Track 1000 is an example of track 102 (FIG. 1). Rail 1010 and rail 1012 are mounted to base 1002 using brackets (not shown). An example of these brackets are bracket 411 and bracket 413 (FIG. 4). Cover member 1004 and cover member 1008 are mounted to the brackets using fasteners such as screw 1026 and screw 1028. Optionally holes (not shown) through which the screws 1026, 1028 pass may be slotted to allow for adjustment of the cover members' positions. To ensure proper spacing between cover member 1004 and cover member 1008 (such as gap 450 and gap 452 in FIG. 4), jig 1022 and jig 1024 may be placed between cover member 1004 and cover member 1008 during assembly and removed thereafter. This reduces the chance that a portion of a workpiece carrier, such as puck 230 (FIG. 2), contacts cover member 1004 and cover member 1008, thus mitigating the chance of generating particles.

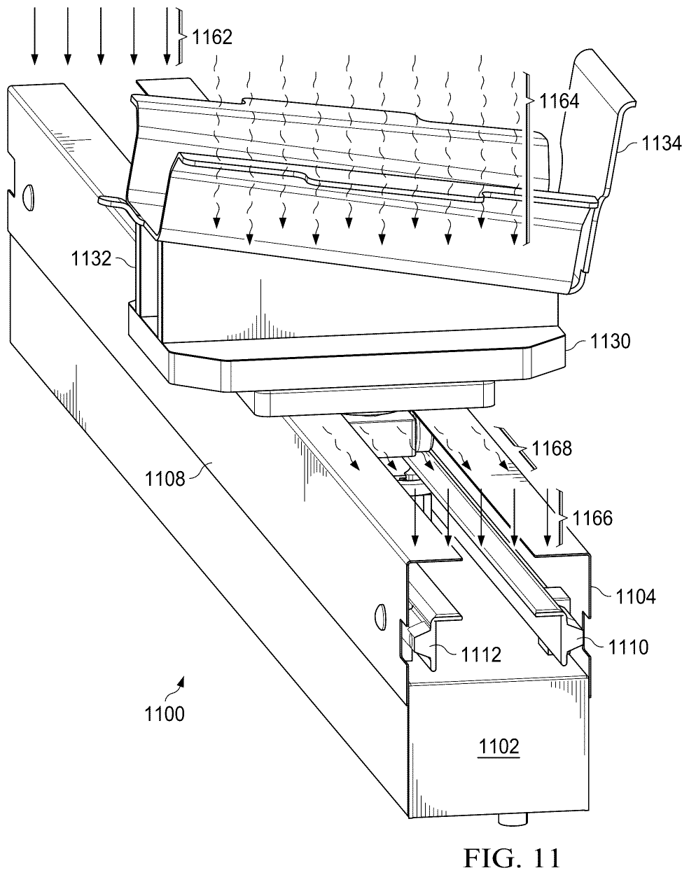

FIG. 11 is a view of an example track 1100 illustrating an example of airflow around a transporter assembly. Track 1100 is an example of track 102 (FIG. 1). Air movement in a semiconductor manufacturing facility, or other clean room, is generally laminar flow from ceiling to floor, in part to ensure that any particles are quickly removed with minimal turbulence that could otherwise increase the residence time in the fab environment. A typical cleanroom filtration system provides air flow through filters in the ceiling of the cleanroom with return air flowing through filters in the floor. Air flow vectors 1162, 1164, 1166, and 1168 illustrate such air flow around puck 1130, carrier base 1132 and receiver 1134 together, which together are an example of workpiece carrier 118 (FIG. 1). Puck 1130 rides on rail 1110 and rail 1112, which are mounted to track base 1102. Cover member 1104 and cover member 1108 cover rail 1110, rail 1112 as previously described, as well as a portion of puck 1130 that is in contact with rail 1110 and rail 1112. Unobstructed movement of puck 1130 along rail 1110 and rail 1112 is provided by proper spacing between the cover members 1104 and 1108 as previously described. Notably, airflow is expected to suppress movement of particles within the area enclosed by the cover members 1104 and 1108 into the production environment in general, and the workpieces being transported in particular Optionally, suction may be provided within the enclosed area, e.g. by orifices within the track base 1102, to further encourage particle segregation.

Modifications are possible in the examples described, and other examples are possible, within the scope of the claims.

What is claimed is:

1. A material movement track, comprising:
a track base having a top surface;
a first rail connected to the track base and having a first major surface extending over the top surface;
a second rail connected to the track base and having a second major surface extending over the top surface;
a first cover member extending from a first side of the track base over the first major surface of the first rail; and
a second cover member extending from a second side of the track base over the second major surface of the second rail and forming a gap between the first cover member and the second cover member.

2. The material movement track as in claim 1, wherein:
the first cover member includes a first side portion oriented normal to the top surface and a first top portion parallel to the top surface; and
the second cover member includes a second side portion oriented normal to the top surface and a second top portion parallel to the top surface.

3. The material movement track of claim 1, further comprising:
a workpiece carrier, the workpiece carrier including:
a first bearing coupled to the workpiece carrier, the at least one bearing configured to contact the first rail and support the workpiece carrier;
a second bearing coupled to the workpiece carrier, the at least one bearing configured to contact the second rail and support the workpiece carrier;
a support extending upward from the workpiece carrier through the gap; and
a receiver mounted on an end of the support distal from the workpiece carrier.

4. The material movement track as in claim 1, wherein the first cover member extends past the first major surface toward a midpoint between the first and second cover members.

5. The material movement track as in claim 1, wherein the first cover member has a non-planar major surface.

6. The material movement track as in claim 1, wherein the first cover member extends through a switch portion of the material movement track.

7. The material movement track as in claim 1, wherein the first cover member covers a switch actuator of the material movement track.

8. A method of forming a material movement track, comprising:
providing a track base having:
a top surface;
a first rail connected to the track base and having a first major surface extending over the top surface; and
a second rail connected to the base and having a second major surface extending over the top surface;
connecting a first cover member extending from a first side of the base over the first rail; and
connecting a second cover member extending from a second side of the base over the second rail and forming a gap between the first and second cover members.

9. The method of claim 8, further comprising:
providing a workpiece carrier, the workpiece carrier including;
a first bearing coupled to the car, the at least one bearing configured to contact the first rail and support the workpiece carrier; and
a second bearing coupled to the car, the at least one bearing configured to contact the second rail and support the workpiece carrier,
wherein the first cover member extends directly over the first bearing and the second cover member extends directly over the second bearing.

10. The method of claim 8, further comprising:
providing a workpiece carrier, the workpiece carrier including;
a first bearing coupled to the car, the at least one bearing configured to contact the first rail and support the workpiece carrier; and
a second bearing coupled to the car, the at least one bearing configured to contact the second rail and support the workpiece carrier,
wherein the first cover member extends past the first rail toward a midpoint between the first and second cover members.

11. The method of claim 8, wherein:
the first cover member includes a first side portion oriented normal to the top surface and a first top portion parallel to the top surface; and
the second cover member includes a second side portion oriented normal to the top surface and a second top portion parallel to the top surface.

12. The method of claim 9, wherein the first cover member has a non-planar major surface and the second cover member has a non-planar major surface.

13. The method of claim 9, wherein the material movement track is configured to transport semiconductor wafers between process work stations.

14. A method of transporting a semiconductor workpiece, comprising:
providing a material movement track for movement of a workpiece carrier, the track including:
a base having a top surface;
a first rail connected to the base and having a first major surface extending over the top surface;
a second rail connected to the base and having a second major surface extending over the top surface;
a first cover member extending from a first side of the base over the first rail; and
a second cover member extending from a second side of the base over the second rail and forming a gap between the first and second cover members.

15. The method of claim 14, wherein the material movement track is suspended from a ceiling.

16. The method of claim 14, further comprising providing the workpiece carrier, wherein the workpiece carrier includes:
a first bearing coupled to the workpiece carrier, the at least one bearing configured to contact the first rail and support the workpiece carrier;
a second bearing coupled to the car, the at least one bearing configured to contact the second rail and support the workpiece carrier,
wherein the first cover member extends directly over the first bearing and the second cover member extends directly over the second bearing.
